(19) United States
(12) Patent Application Publication
(10) Pub. No.: US 2009/0033428 A1
(43) Pub. Date: Feb. 5, 2009

(54) VOLTAGE CONTROLLED OSCILLATOR

(75) Inventor: Satyanarayana Reddy KARRI, Konkuduru (IN)

Correspondence Address: THOMAS, KAYDEN, HORSTEMEYER & RISLEY, LLP, 600 GALLERIA PARKWAY, S.E., STE 1500, ATLANTA, GA, 30339-5994, US

(73) Assignee: MEDIATEK SINGAPORE PTE LTD., Ayer Rajah Crescent (SG)

(21) Appl. No.: 12/124,254

(22) Filed: May 21, 2008

Related U.S. Application Data
(60) Provisional application No. 60/952,605, filed on Jul. 30, 2007.

(51) Int. Cl. H03L 7/04

(52) U.S. Cl. 331/17

(57) ABSTRACT

An integrated circuit is provided. The integrated circuit comprises a voltage controlled oscillator and a first compensation capacitor. The voltage controlled oscillator generates an oscillation signal. The first compensation capacitor, coupled in parallel to the voltage controlled oscillator, receives a control voltage to generate a negative temperature coefficient capacitance to compensate for frequency drift of the oscillation signal. The control voltage is temperature dependent.

### CROSS REFERENCE

This application claims the benefit of U.S. provisional application Ser. No. 60/952,605 filed Jul. 30, 2007, the subject matter of which is incorporated herein by reference.

### BACKGROUND OF THE INVENTION

1. Field of the Invention

The invention relates to integrated circuits, and in particular, to a voltage controlled oscillator in an integrated circuit.

2. Description of the Related Art

Voltage controlled oscillators (VCO) are widely used in electronics circuits. Typically, VCOs are used in local oscillators (LO) to generate signals for frequency upconversion or downconversion in transmitters or receivers, or used in phase locked loops (PLL) to provide clock signals in synchronous circuits. A wireless device such as a cellular phone in a wireless communication system may employ multiple VCOs to generate LO signals for transmitter and receiver circuitry and clock signals for digital circuitry.

Typically, a VCO includes both active and passive devices. Problems such as frequency variation arise from the passive components and problems such as output swing voltage variation, phase noise variation stem from the active devices.

FIG. 1 is a block diagram of a conventional VCO, comprising inductor 100, varactor 102, and parasitic capacitor 104 coupled in parallel. Inductor 100 and varactor 102 collectively produce an oscillation signal with an oscillation frequency of:

$$f = \frac{1}{\sqrt[2 π]{{LC}_{v}}} \qquad ( 1 )$$

where f is the oscillation frequency;

L is inductance of inductor 100; and

Cᵥ is capacitance of varactor 102.

FIG. 11 is a schematic diagram of realization of a conventional VCO according to FIG. 1. To compensate for power loss in inductor 100, the VCO circuits typically employ active components such as the cross-coupled MOS transistors in FIG. 11. The active components, while compensating for loss in inductor 100, also contributes to undesired parasitic capacitance Cₚ, represented by parasitic capacitor 104 in FIG. 1. The undesired parasitic capacitance is temperature dependent, typically increasing with temperature. Thus the oscillation frequency of the VCO considering parasitic capacitance Cₚ is:

$$f = 1 / \sqrt[2 π]{L ( {C}_{v} + {C}_{p} )} \qquad ( 2 )$$

where f is the oscillation frequency, L is inductance of inductor 100, Cᵥ is varactor capacitance of varactor 102, and Cₚ is the parasitic capacitance.

A problem of frequency drift of the output oscillation signal is due to the reverse biased diode intrinsic to the active devices. The reverse bias diode acts as a voltage dependent capacitor and the diode capacitance equation is as the follows:

$${C}_{j} = \frac{{C}_{j 0}}{\sqrt[γ]{{V}_{D} + {ψ}_{0}}} \qquad ( 3 )$$

where V_{D} is the reverse bias potential applied across the diode and Ψ₀ is the built-in potential of the diode. Reverse biased potential V_{D} varies by −2 mV/° C., and subsequently diode capacitance Cⱼ increases with the temperature.

Parasitic capacitance Cₚ is a combination of drain to bulk capacitance C_{db}, gate to source capacitance C_{gs}, and miller effect of gate to drain capacitance C_{gd}, or:

Cₚ=C_{db}+C_{gs}+C_{gd}(1+A) (4)

where A is a voltage gain provided by gₘR; with gₘ being transconductance of each MOS transistor and R being impedance of the LC tank. The drain to bulk capacitance C_{db} and varactor capacitance Cᵥ follow the diode capacitance equation (3) and hence increases with temperature. Concurrently, transconductance gₘ of the transistor decreases as temperature increases. Typically, the capacitance C_{db} and Cᵥ is a stronger factor than transconductance gₘ for determining overall capacitance (Cᵥ+Cₚ) of the VCO circuit, thus the VCO has a positive temperature coefficient and increases with temperature.

Thus, a need exists for a voltage controlled oscillator capable of compensating for frequency drift of the oscillation signal and output voltage swing variation.

### BRIEF SUMMARY OF THE INVENTION

A detailed description is given in the following embodiments with reference to the accompanying drawings.

An integrated circuit is disclosed, comprising a voltage controlled oscillator and a first compensation capacitor. The voltage controlled oscillator generates an oscillation signal. The first compensation capacitor, coupled in parallel to the voltage controlled oscillator, receives a control voltage to generate a negative temperature coefficient capacitance to compensate for frequency drift of the oscillation signal. The control voltage is temperature dependent.

According to another embodiment of the invention, an integrated circuit comprises a voltage controlled oscillator and a first compensation capacitor. The voltage controlled oscillator comprises an inductor, a varactor, a cross-coupled N-type transistor pair, and a cross-coupled P-type transistor pair, all coupled in parallel, and generates an oscillation signal. The first compensation capacitor, coupled in parallel to the inductor, the varactor, the cross-coupled N-type and P-type transistor pair, receives a control voltage to generate a negative temperature coefficient capacitance to compensate for frequency drift of the oscillation signal the control voltage is temperature dependent.

### BRIEF DESCRIPTION OF THE DRAWINGS

The invention can be more fully understood by reading the subsequent detailed description and examples with references made to the accompanying drawings, wherein:

FIG. 1 is a block diagram of a conventional voltage controlled oscillator.

FIG. 2 is a block diagram of an exemplary voltage controlled oscillator according to the invention.

FIG. 3 is a schematic diagram of an exemplary voltage controlled oscillator according to the invention.

FIG. 4 is a schematic diagram of another exemplary voltage controlled oscillator according to the invention.

FIG. 5 is a schematic diagram of yet another exemplary voltage controlled oscillator according to the invention.

FIG. 6a shows the relationship of control voltage V_{C} and capacitance variation of compensation capacitors C520 and C522 in FIG. 5.

FIG. 6b shows the relationship of voltage (V_{B}-V_{C}) and capacitance variation of compensation capacitors C524 and C526 in FIG. 5.

FIG. 7 is a schematic diagram of still another exemplary voltage controlled oscillator according to the invention.

FIG. 8a is a circuit schematic of exemplary compensation capacitors in FIG. 5.

FIG. 8b is a circuit equivalent diagram of the compensation capacitors in FIG. 8a.

FIG. 8c shows a relationship of control voltage VPTAT and capacitances C_{gd} and C_{gs} in FIG. 8b.

FIG. 9 is a schematic diagram of still yet another exemplary voltage controlled oscillator according to the invention.

FIG. 10 is a schematic diagram of yet another exemplary voltage controlled oscillator according to the invention.

FIG. 11 is a schematic diagram of realization of a conventional VCO according to FIG. 1.

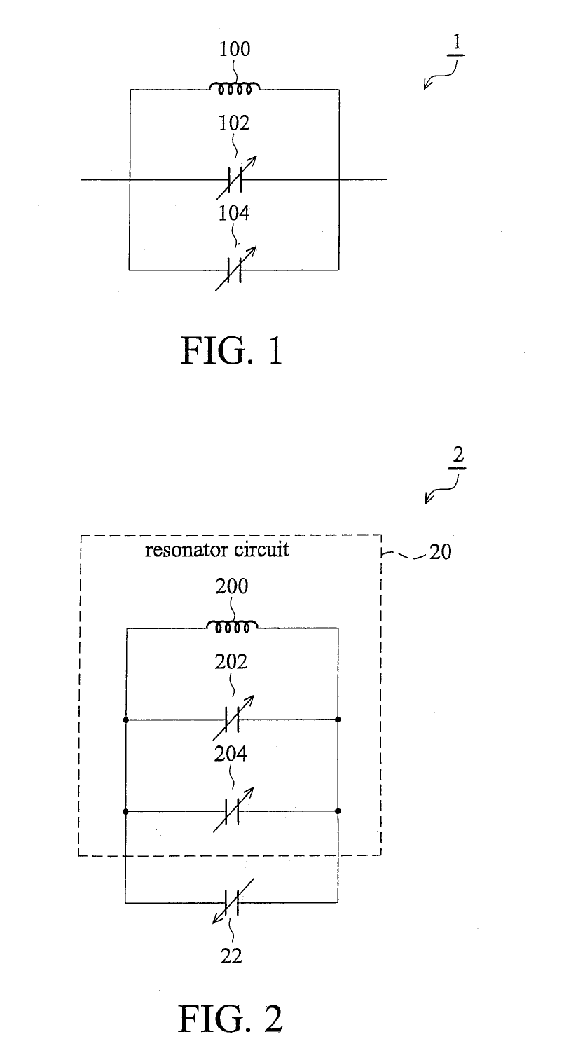

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

By differentiating Equation (2), the temperature coefficient of the oscillation frequency f is shown as:

$$1 / f \frac{\partial f}{\partial T} = 1 / ( {C}_{p} + {C}_{v} ) \frac{\partial ( {C}_{p} + {C}_{v} )}{\partial T} + 1 / C \partial C / \partial T \qquad ( 5 )$$

For a zero temperature coefficient,

$$1 / f \frac{\partial f}{\partial T}$$

is zero, and:

$$1 / ( {C}_{p} + {C}_{v} ) \frac{\partial ( {C}_{p} + {C}_{v} )}{\partial T} = - 1 / C \partial C / \partial T , \qquad ( 6 )$$

wherein

$$- 1 / C \frac{\partial C}{\partial T}$$

a negative coefficient capacitance, i.e., the capacitance decreases as the temperature increases. Equation (6) shows that by incorporating a capacitor with negative temperature coefficient capacitance into the conventional VCO circuit, the overall capacitance variation is decreased.

FIG. 2 is a block diagram of an exemplary voltage controlled oscillator according to the invention, comprising resonator circuit 20 and compensation capacitor 22 in parallel. Resonator circuit 20 comprises inductor 200, varactor 202, and parasitic capacitor 204, all in parallel.

Resonator circuit 20 is an LC tank circuit resonating at an oscillation frequency. Varactor 202 and parasitic capacitor 204 have capacitances proportional to the absolute temperature (PTAT) and 206 has a capacitance complementary to the absolute temperature (CTAT). As the temperature increases, the PTAT capacitances of varactor 202 and parasitic capacitor 204 are compensated by the CTAT capacitance of 206, rendering a substantially constant capacitance. Since the additional negative temperature coefficient capacitance can cause the oscillation frequency to decrease, the circuit design takes the effect into consideration. In practice, voltage dependent capacitors can be employed for the realization of a negative temperature coefficient capacitance.

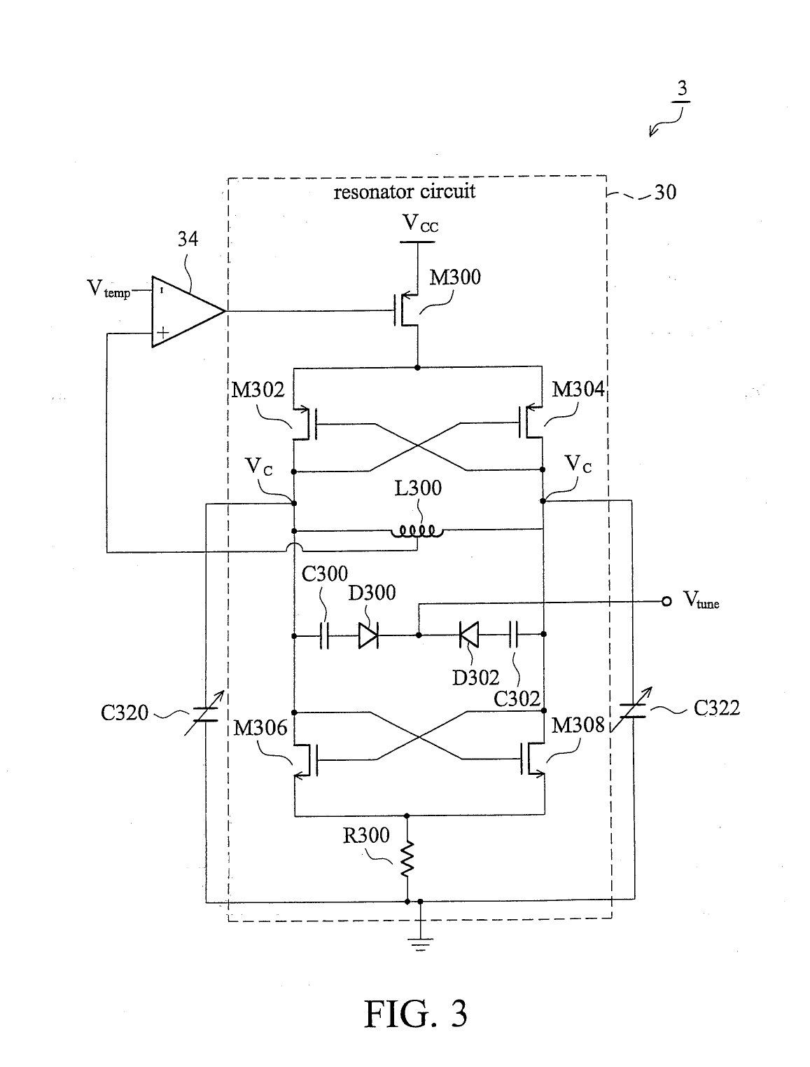

FIG. 3 is a schematic diagram of an exemplary voltage controlled oscillator according to the invention, comprising resonator circuit 30, C320 and C322, and operational amplifier 34. Resonator circuit 30 is coupled to operational amplifier 34, and C320 and C322.

Resonator circuit 30 comprises M300, cross-coupled MOS transistors M302 and M304, inductor L300, varactors C300 and C302, diodes D300 and D302, cross-coupled MOS transistors M306 and M308, and resistor R300.

Inductor L300, varactors C300 and C302 form a resonator circuit providing an oscillation signal with a frequency predetermined by Equation (2). Inductor L300 may be fabricated on-chip or implemented with external circuit components. Varactors C300 and C302 may be adjusted through signal Vtune to obtain a desired oscillation frequency of 3. Varactors C300 and C302 may comprise a plurality of varactors, in series or parallel, to accommodate a desired tuning range. The oscillation signal is a differential signal pair across the both ends of the resonator circuit. Cross-coupled NMOS transistors M302 and M304, and PMOS transistors M306 and M308 provide negative Gₘ devices driving to the resonator circuit.

Compensation capacitors C320 and C322 are voltage dependent capacitors controlled by control voltage V_{C}. Control voltage V_{C} may be proportional to the absolute temperature or complementary to the absolute temperature. In the embodiment, the capacitance of capacitors C320 and C322 decrease with the increase of control voltage V_{C}, and vise versa. Thus, when control voltage V_{C} is proportional to the absolute temperature, capacitors C320 and C322 provide negative temperature coefficient capacitance, and when control voltage V_{C} is complementary to the absolute temperature, capacitors C320 and C322 produce positive temperature coefficient capacitance. The varactor capacitances of varactors C300 and C302 and parasitic capacitance of the reverse diode in the MOS transistors increase with temperature. By applying PTAT control voltage V_{C} across compensation capacitors C320 and C322, the positive temperature coefficient capacitance of the varactor capacitances and the parasitic capacitance are compensated by the temperature coefficient capacitance of the compensation capacitors, rendering a substantially constant capacitance and a stable oscillation frequency. In other embodiments, the capacitances of compensation capacitors C320 and C322 increase when voltages are applied across the capacitors, and CTAT control voltage V_{C} is employed to provide the required negative temperature coefficient capacitance. In some other embodiment, the slope of control voltage V_{C} is increased to increase the temperature coefficient of compensation capacitors C320 and C322, according to Equation (6). Note since extra steepness of control voltage V_{C} may affect the DC operating condition of the voltage controlled oscillator circuit, the output oscillation signal may be unstable when temperature varies.

Control voltage V_{C} is established at both ends of inductor L300 by directing a temperature dependent voltage to the center thereof. For example, a PTAT voltage is provided at the inverting input of operational amplifier 34 so that a voltage level at the center of inductor L300 follows the PTAT voltage, which is then sensed by the error amplifier (transistors M302˜M308), rendering control voltage V_{C} that is a substantially identical to the inputted PTAT voltage through negative feedback.

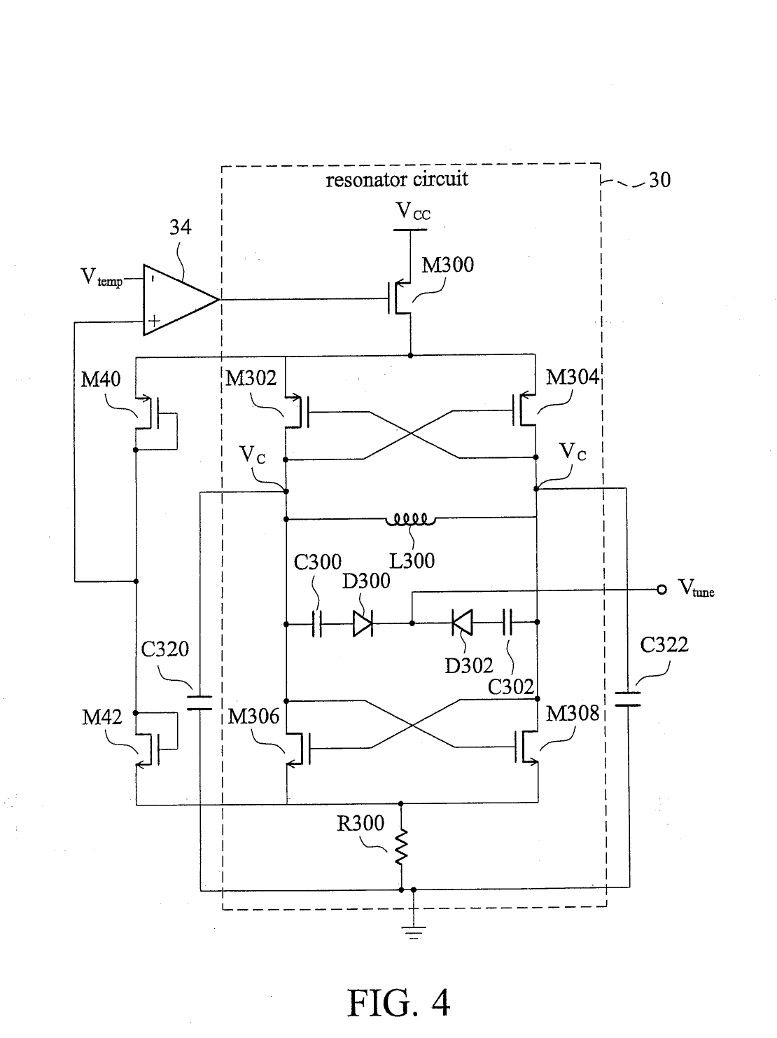

FIG. 4 is a schematic diagram of another exemplary voltage controlled oscillator according to the invention, comprising resonator circuit 30, compensation capacitors C320 and C322, operational amplifier 34, and MOS transistors M40 and M42. resonator circuit 30, C320 and C322, and operational amplifier 34 are explained in FIG. 3, thus detailed description is omitted here for brevity. FIG. 4 depicts another way of providing temperature dependent voltage V_{C}.

The voltage controlled oscillator in FIG. 4 employs MOS transistors M40 and M42 to generate control voltage V_{C} for providing negative temperature coefficient capacitance of compensation capacitors C320 and C322. MOS transistors M40 and M42 are diode connected and connected to one another face-to-face. The source terminal of transistor M40 is coupled to that of the cross-coupled MOS transistors M302 and M304, and the source terminal of transistor M42 is coupled to that of the cross-coupled MOS transistors M306 and M308, so that transistors M40 and M42 are replica of transistors M302 and M306 (or transistors M304 and M308), resulting in control voltage V_{C} that is identical to the voltage at the non-inverting terminal of operational amplifier 34, or temperature dependent input Vₜₑₘₚ.

By varying the voltage across compensation capacitors C320 and C322, the temperature coefficient thereof can be changed to compensate for the frequency drift over temperature. While the voltage controlled oscillators in FIG. 3 and FIG. 4 only employ PTAT control voltage V_{C} to change the voltage across the compensation capacitors, a CTAT voltage V_{CTAT} may further be coupled to the compensation capacitors, such that PTAT control voltage V_{C} and CTAT voltage V_{CTAT} establish an increased voltage difference (V_{C}−V_{CTAT}) across the compensation capacitors, generating an increased voltage slope as the temperature changes, thereby providing an increased negative temperature coefficient capacitance for compensation, thus allowing a larger margin of temperature variation.

As the temperature rises, control voltage V_{C} rises with PTAT input voltage Vₜₑₘₚ, the bias conditions of transistors M302 through M308 also changes. Transconductance gₘ of the transistors M302 through M308 increase with control voltage V_{C}, causing increase in currents, Miller capacitance (C_{gd}(1+A)), and the reverse bias voltage across drain to bulk capacitance of the transistors. Consequently additional negative temperature coefficient capacitance is needed to accommodate the increased parasitic capacitance Cₚ of the voltage controlled oscillators in FIGS. 3 and 4.

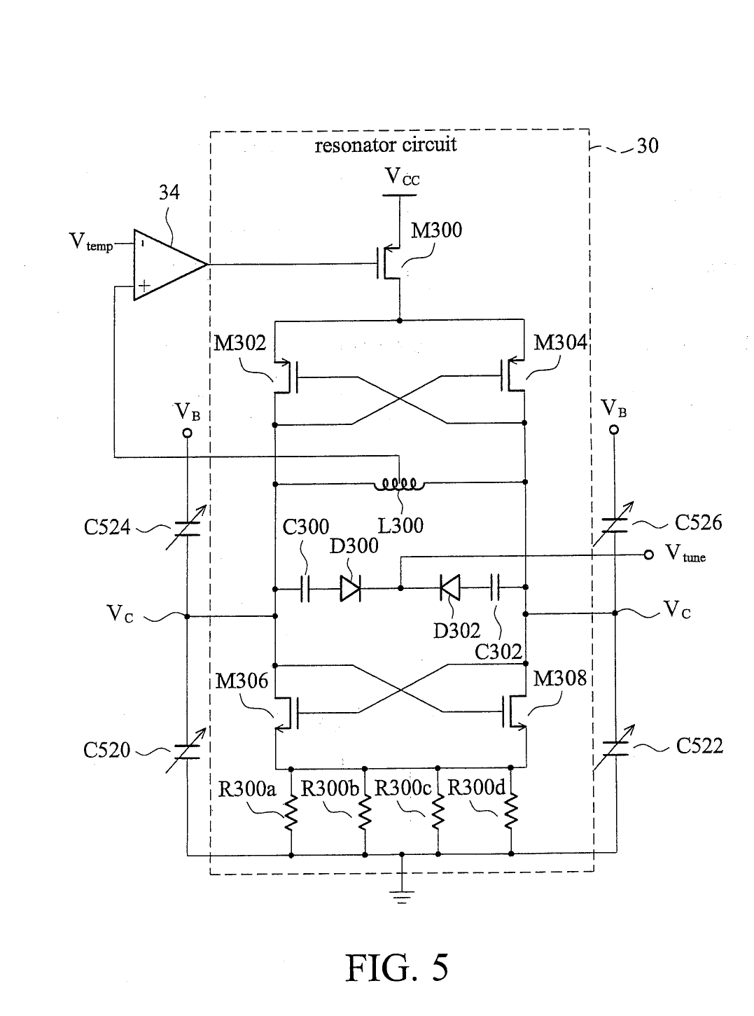

FIG. 5 is a schematic diagram of yet another exemplary voltage controlled oscillator according to the invention, comprising resonator circuit 30, operational amplifier 34, and compensation capacitors C520 to C526. Resonator circuit 30 is coupled to operational amplifier 34, and compensation capacitors C520 to C526. Capacitors C520 and C524 are coupled in series, and C522 and C526 are also in series.

Compensation capacitors C520 and C522 act as capacitors C320 and C322, and provides decreased capacitances as the voltage thereacross increases. On the contrary, compensation capacitors C524 and C526 provide decreased capacitances as the voltage thereacross decreases, i.e., positive temperature coefficient capacitances. Compensation capacitors C524 and C526 receive control voltage V_{C} and bias voltage V_{B} from two ends of the devices. Since bias voltage V_{B} is fixed regardless of temperature variation, assuming control voltage V_{C} with PTAT input voltage Vₜₑₘₚ, compensation capacitors C524 and C526 experience a CTAT voltage (V_{B}−V_{C}) and produce positive temperature coefficient capacitances. Therefore, the combined capacitances for capacitors C520 and C524, and C522 and C526 decrease as the temperature increases.

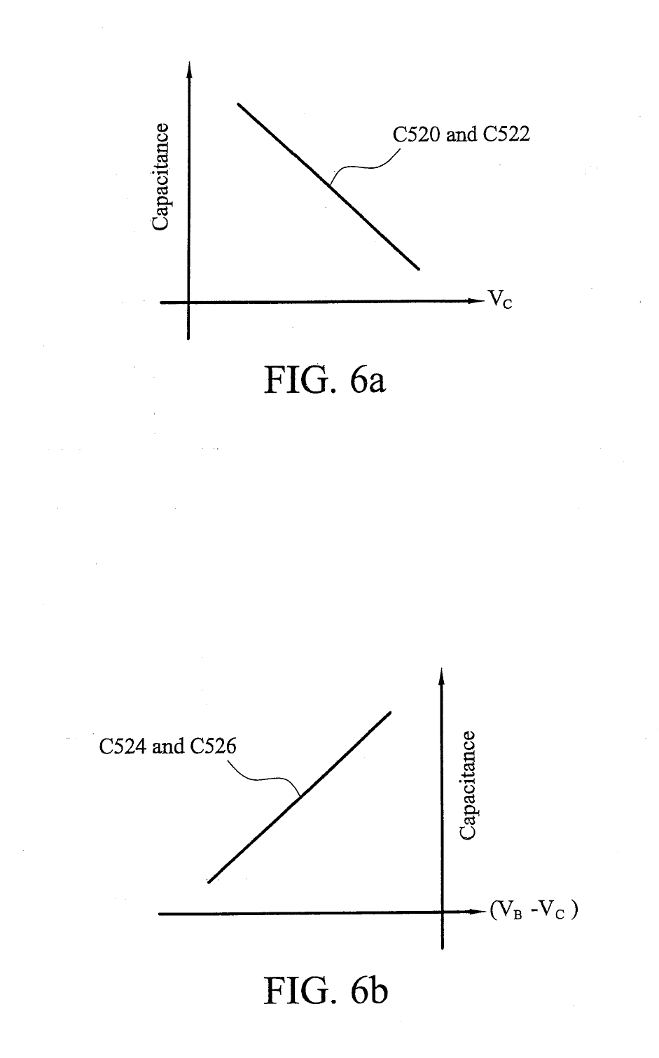

FIG. 6a shows the relationship of control voltage V_{C} and capacitance variation of compensation capacitors C520 and C522 in FIG. 5. Compensation capacitors C520 and C522 exhibit decreased capacitance variation as PTAT voltage V_{C} increases, rendering voltage controlled negative coefficient capacitances.

FIG. 6b shows the relationship of voltage (V_{B}−V_{C}) and capacitance variation of compensation capacitors C524 and C526 in FIG. 5. Compensation capacitors C524 and C526 exhibit decreased capacitance variation as CTAT voltage (V_{B}−V_{C}) decreases, rendering voltage controlled positive coefficient capacitances. When temperature increases, PTAT voltage V_{C} increases and CTAT voltage (V_{B}−V_{C}) decreases, the combined capacitances for capacitors C520 and C524, and C522 and C526 decrease accordingly, providing the negative temperature coefficient capacitances to compensate for the increased varactor and parasitic capacitances, the resulting in reduced frequency drift of the oscillation signal over the temperature variation.

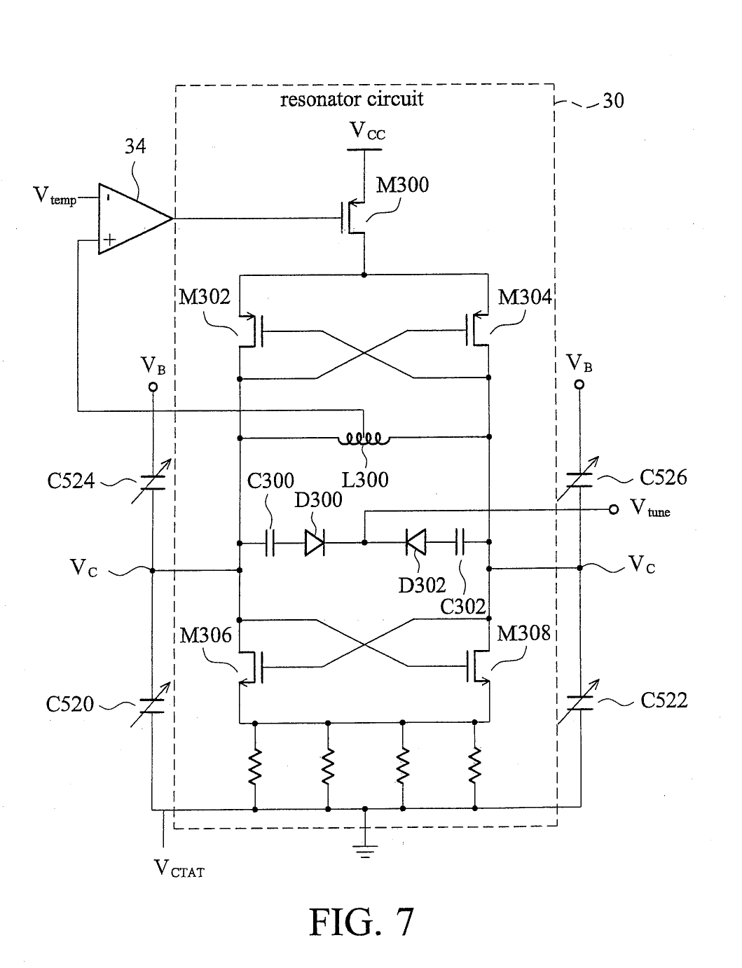

FIG. 7 is a schematic diagram of still another exemplary voltage controlled oscillator according to the invention. The voltage controlled oscillator in FIG. 7 has an identical circuit connection as in FIG. 5, except that the ground plate of compensation capacitors C520 and C522 are tied to CTAT voltage V_{CTAT} to increase the voltage difference (V_{C}−V_{CTAT}) thereacross. The increased voltage difference (V_{C}−V_{CTAT}) produces increased slope of a PTAT voltage across the compensation capacitor, generating increased negative temperature coefficient capacitances, and providing sufficient capacitance variation margin to compensate for the frequency drift of the oscillation signal for voltage controlled oscillator in FIG. 7.

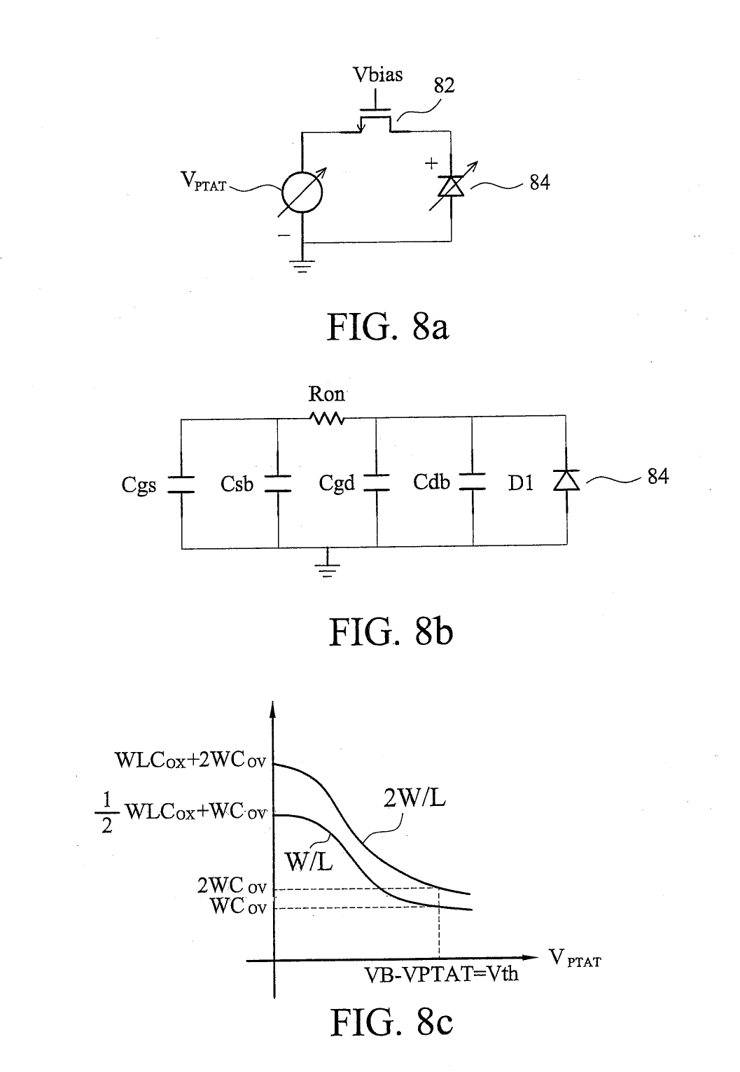

FIG. 8a is a circuit schematic of exemplary compensation capacitors in FIGS. 5 and 7, comprising PTAT voltage source VPTAT, transistor 82, and diode 84. 82 is coupled to PTAT voltage source V_{PTAT} and 84. FIG. 8a provides an exemplary circuit realization for the compensation capacitors having PTAT and CTAT voltage controlled capacitances.

The voltage dependent capacitors may be implemented by PN-junction varactors or MOS varactors. MOS transistors in the triode region can be used as a voltage dependent capacitor. Diode 84 serves two purposes, namely, keeping the voltage potentials at the source and drain terminals of transistor 82 equivalent, and generating decreased capacitance as the temperature increases.

FIG. 8b is an equivalent circuit diagram of the compensation capacitors in FIG. 8a, comprising gate-to-source capacitance C_{gs}, source-to-bulk capacitance C_{sb}, gate-to-drain capacitance C_{gd}, drain-to-bulk capacitance C_{db}, turn-on resistance Rₒₙ, and diode 84.

Since turn-on resistance Rₒₙ is negligible, the compensation capacitance C is (C_{gd}+C_{gs}+C_{db}+C_{sb}). Source-to-bulk capacitance C_{sb}, drain-to-bulk capacitance C_{db}, and diode capacitance C₈₄ constitute C520 and C522, as shown in FIGS. 5 and 7, decrease as PTAT voltage V_{PTAT} increases. Gate-to-drain capacitance C_{gd} and gate-to-source capacitance C_{gs} varies according to temperature dependent voltage V_{PTAT}, and the relationship is depicted in FIG. 8c. FIG. 8c shows that as temperature dependent voltage V_{PTAT} increases, the voltage (V_{bias}−V_{PTAT}) across gate-to-source and gate-to-drain terminals decreases, gate-to-drain capacitance C_{gd} and gate-to-source capacitance C_{gs} decrease from ½WLCₒₓ+WCₒᵥ to WCₒᵥ, where W and L are the channel width and length of transistor 82, and Cₒₓ and Cₒᵥ are the oxide and overlap capacitance per unit of transistor 82. Capacitances C_{gd} and C_{gs} decrease with PTAT voltage V_{PTAT}, and capacitance (C_{gd}+C_{gs}) represents C524 and C526 in FIGS. 5 and 7.

While the embodiments carried out in FIGS. 8a to 8c are based on an NMOS transistor, embodiments are equally valid for a PMOS transistor.

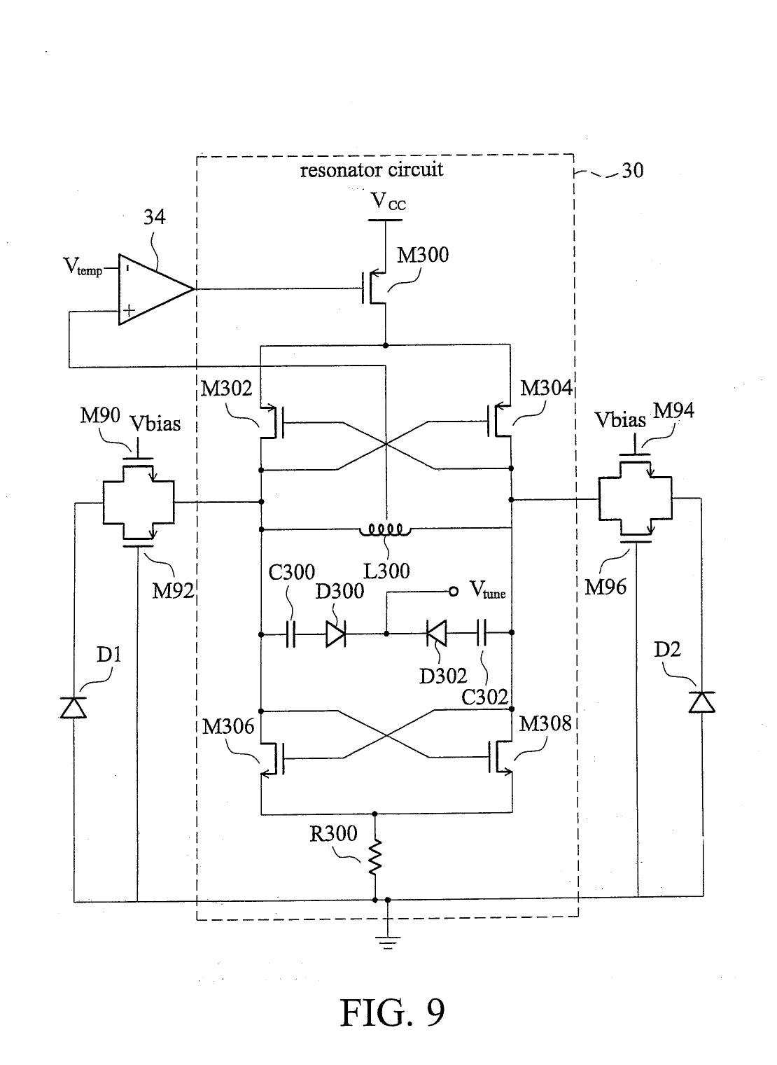

FIG. 9 is a schematic diagram of still yet another exemplary voltage controlled oscillator according to the invention, comprising resonator circuit 30, operational amplifier 34, transistors M90 through M96, and diodes D1 and D2. Resonator circuit 30 is coupled to 32, and transistors M90 through M96, and subsequently to diodes D1 and D2. The voltage controlled oscillator in FIG. 9 utilizes circuit topology revealed in FIG. 5.

Based on the analysis provided in FIGS. 8a to c, transistors M90 and M92 in conjunction with diode D1 provide compensation capacitors C520 and C524, as shown in FIG. 5, transistors M94 and 96 and diode D2 provide compensation capacitors C522 and C526. When the temperature increases, PTAT input voltage Vₜₑₘₚ and PTAT control voltage V_{C} increase, controlling transistors M90 through M96 and diodes D1 and D2 to provide decreased capacitances to compensate for the increased varactor and parasitic capacitances and reduce the frequency drift of the oscillation signal.

While both PMOS and NMOS transistors are employed for providing compensation capacitors, PMOS or NMOS transistors alone can be used to serve the purposes of the invention. Those skilled in the art can modify the voltage controlled oscillator circuit where appropriate without deviating from the general principles of the invention.

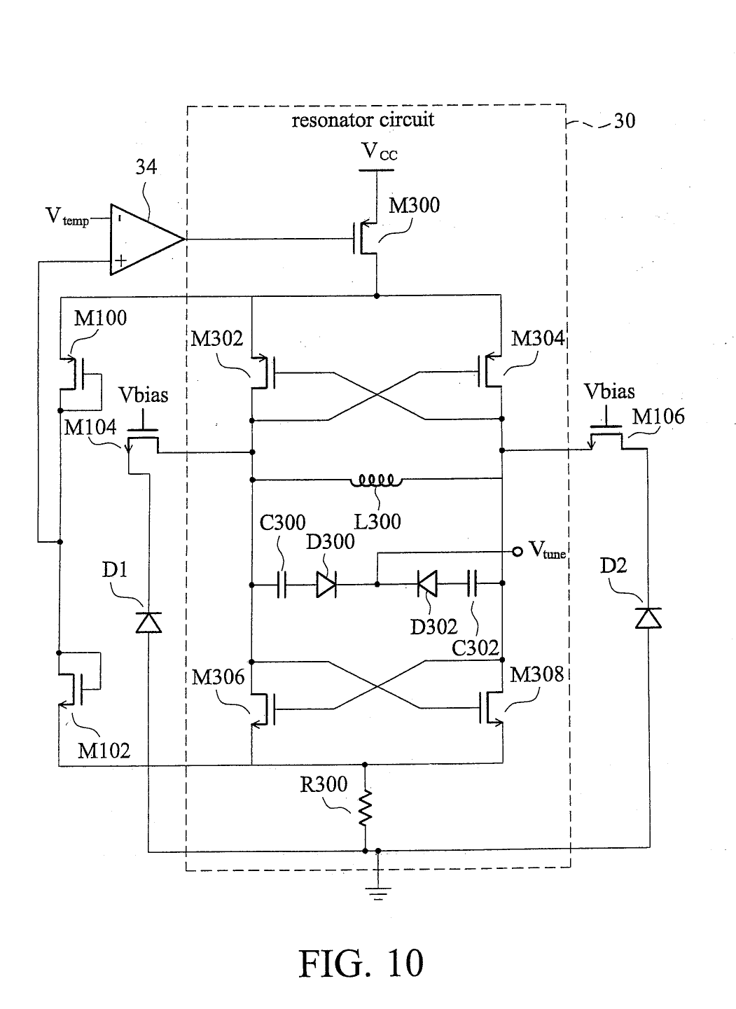

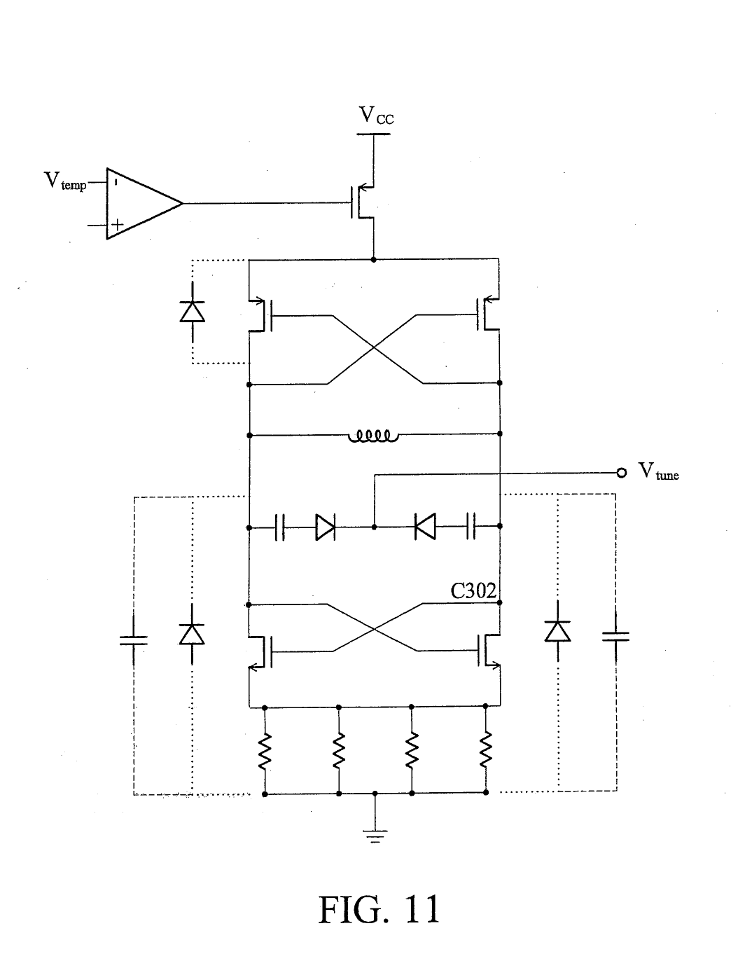

FIG. 10 is a schematic diagram of yet another exemplary voltage controlled oscillator according to the invention, comprising resonator circuit 30, operational amplifier 34, transistors M100 through M106, and diodes D1 and D2. Resonator circuit 30 is coupled to operational amplifier 34, transistors M100 through M106. Transistor M104 and M106 are coupled to diodes D1 and D2, respectively. The voltage controlled oscillator in FIG. 10 utilizes circuit topology revealed in FIGS. 4 and 5.

Transistors M100 and M102 are diode connected and serve as copies of transistors M302 and M306 (transistors M304 and M308), such that the voltage potential at the non-inverting terminal of operational amplifier 34 can be reproduced as control voltage V_{C}. As the temperature increases, control voltage V_{C} increases, the capacitances provided by transistor M104 and diode D1 decreases, thereby compensating for the increased varactor capacitance and the parasitic capacitance of resonator circuit 30, reducing the frequency drift of the output oscillation signal.

The temperature compensated voltage controlled oscillators disclosed herein may be used for RFICs, analog ICs, DSPs, digital ICs, ASICs (application specific integrated circuits), controllers, and processors. While the disclosures herein utilize MOSFET transistor technology to implement the circuits, the temperature compensated voltage controlled oscillators disclosed herein may be realized by BJT transistor technology, and the like. People in the art should also appreciate that the complementary transistor types can be used in place of the transistor types in the embodiments without deviating from the principle of the invention, e.g., P-type transistor in place of N-type, and vice versa.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. An integrated circuit, comprising:
a voltage controlled oscillator, generating an oscillation signal; and
a first compensation capacitor, coupled in parallel to the voltage controlled oscillator, receiving a control voltage to generate a negative temperature coefficient capacitance to compensate for frequency drift of the oscillation signal;
wherein the control voltage is temperature dependent.

2. The integrated circuit of claim 1, wherein the control voltage is proportional to absolute temperature (PTAT) or complementary to absolute temperature (CTAT).

3. The integrated circuit of claim 1, wherein the voltage controlled oscillator comprises an inductor and a varactor coupled in parallel, and the inductor receives a temperature dependent voltage at a center thereof to establish the control voltage thereacross.

4. The integrated circuit of claim 1, wherein the voltage controlled oscillator comprises an inductor, a varactor, a cross-coupled N-type transistor pair, and a cross-coupled P-type transistor pair, coupled in parallel, and the integrated circuit further comprises two diode connected transistors coupled in series, coupled to the cross-coupled N-type and P-type transistor pairs, receiving a temperature dependent voltage to establish the control voltage at two ends of the inductor and the varactor.

5. The integrated circuit of claim 1, wherein the first compensation capacitor receives the control voltage V_{C} at one terminal, and further receives a second temperature dependent voltage V₂ to establish a voltage difference (V_{C}−V₂) thereacross to generate the negative temperature coefficient capacitance, and the second temperature dependent voltage V2 has a complementary temperature dependent voltage type to the control voltage.

6. The integrated circuit of claim 1, further comprising a second compensation capacitor coupled to the first compensation capacitor and the voltage controlled oscillator, receiving the control voltage and a bias voltage to establish another temperature dependent voltage thereacross and generate a second negative temperature coefficient capacitance.

7. The integrated circuit of claim 6, wherein the first and second compensation capacitors comprise:
a first MOS transistor having first gate, first drain, and first source, wherein the first gate receives a fixed bias voltage and the first source receives the control voltage; and
a diode, coupled to the first drain.

8. An integrated circuit, comprising:
a voltage controlled oscillator, comprising an inductor, a varactor, a cross-coupled N-type transistor pair, and a cross-coupled P-type transistor pair, all coupled in parallel, generating an oscillation signal; and
a first compensation capacitor, coupled in parallel to the inductor, the varactor, and the cross-coupled N-type and P-type transistor pair, receiving a control voltage to generate a negative temperature coefficient capacitance to compensate for frequency drift of the oscillation signal;
wherein the control voltage is temperature dependent.

9. The integrated circuit of claim 8, wherein the control voltage is proportional to absolute temperature (PTAT) or complementary to absolute temperature (CTAT).

10. The integrated circuit of claim 8, further comprising an operational amplifier, coupled to the voltage controlled oscillator, receiving an input voltage at an inverting input, coupling to a center of the inductor by a non-inverting input, and outputting to the voltage controlled oscillator, wherein the center of the inductor receives the input voltage to establish the control voltage thereacross, and the input voltage is temperature dependent.

11. The integrated circuit of claim 8, further comprising:
an operational amplifier, coupled to the voltage controlled oscillator, having an inverting input, a non-inverting input, and an output, receiving an input voltage at the inverting input, and outputting the voltage from the output to the voltage controlled oscillator; and
two diode connected transistors coupled in series, coupled to the cross-coupled N-type and P-type transistor pairs, receiving the input voltage from the non-inverting input to establish the control voltage at two ends of the inductor and the varactor;
wherein the input voltage is temperature dependent.

12. The integrated circuit of claim 8, wherein the first compensation capacitor receives the control voltage V_{C} at one terminal, and further receives a second temperature dependent voltage V₂ to establish a voltage difference (V_{C}−V₂) thereacross to generate the negative temperature coefficient capacitance, and the second temperature dependent voltage V2 has a complementary temperature dependent voltage type to the control voltage.

13. The integrated circuit of claim 8, further comprising a second compensation capacitor coupled to the first compensation capacitor and the voltage controlled oscillator, receiving the control voltage and a bias voltage to establish another temperature dependent voltage thereacross and generate a second negative temperature coefficient capacitance.

14. The integrated circuit of claim 13, wherein the first and second compensation capacitors comprise:
a first MOS transistor having first gate, first drain, and first source, the first gate receiving a fixed bias voltage, and the first source receiving the control voltage; and
a diode, coupled to the first drain.
